(19) United States
(12) Patent Application Publication
(10) Pub. No.: US 2014/0295581 A1
(43) Pub. Date: Oct. 2, 2014

(54) METHOD AND APPARATUS TO FABRICATE VIAS IN THE GaN LAYER OF GaN MMICS

(71) Applicant: TransLith Systems, LLC, Bedford, NH (US)

(72) Inventors: Paul Hoff, Bedford, NH (US); Donald Ronning, Nashua, NH (US)

(21) Appl. No.: 14/231,949

(22) Filed: Apr. 1, 2014

Related U.S. Application Data
(60) Provisional application No. 61/807,559, filed on Apr. 2, 2013.

(51) Int. Cl. H01L 21/768; H01L 21/66

(52) U.S. Cl. CPC H01L 21/76804; H01L 22/12
USPC 438/7

(57) ABSTRACT

The method and apparatus to fabricate vias in the gallium nitride (“GaN”) layer of a GaN monolithic microwave integrated circuit (“MMIC”). The method and apparatus create vias in the GaN layer of a GaN MMIC through the use of controlled laser ablation and spectroscopic analysis of SiC and CVD diamond MMICs. The use of spectroscopic measurements helps to control the ablation by detecting a change in layers, including the GaN layer. The method and apparatus uses short pulse length, short wavelength, and a lower threshold intensity to remove material without undue heating or damage to the surrounding areas while retaining depth control.

### CROSS-REFERENCE TO RELATED APPLICATIONS

The present application claims the benefit of U.S. Provisional Application No. 61/807,559, filed Apr. 2, 2013, the content of which is incorporated by reference herein in its entirety.

### TECHNICAL FIELD OF THE INVENTION

The present invention relates to a method and apparatus to fabricate vias in the gallium nitride (“GaN”) layer of a GaN monolithic microwave integrated circuit (“MMIC”). More specifically, it relates to a method and apparatus to create vias in the GaN layer of a GaN MMIC through the use of controlled laser ablation and spectroscopic analysis.

### BACKGROUND OF THE INVENTION

A MMIC is a type of integrated circuit (“IC”) device that operates at microwave frequencies (300 MHz to 300 GHz). MMICs are typically small (from around 1 mm² to 10 mm²) and are amenable to mass production, which has allowed the proliferation of such high frequency devices. MMICs can be fabricated using gallium arsenide (“GaAs”), as it has fundamental advantages over silicon (“Si”), which is the traditional material used in IC manufacture. For example, GaAs provides better device (transistor) speed, which helps with the design of high frequency circuit functions. Gallium nitride (“GaN”) is also an option for MMICs. Because GaN transistors can operate at much higher temperatures and work at much higher voltages than GaAs transistors, they make ideal power amplifiers at microwave frequencies.

A via, or vertical interconnect access, is a vertical electrical connection between different layers of conductors in a physical electronic circuit. Vias enable the construction of high frequency, high power MMICs by providing a low inductance path from the device to the ground plane of the circuit. High power MMIC designs commonly utilize backside vias that are fabricated through a GaAs substrate for GaAs circuits, and through a silicon carbide (“SiC”) or CVD diamond substrate in the case of GaN circuits. GaN is a high band gap material and SiC and CVD diamond, which exhibit high thermal conductivity.

The present invention is a method and apparatus to use controlled laser ablation of GaN to fabricate vias. Current technologies for laser ablation of materials use either long pulses at short wavelength or short pulses at long wavelength. Both technologies have significant shortcomings as described in U.S. patent application Ser. No. 12/800,554, which is incorporated by reference in its entirety.

Conventional chemical or plasma etching techniques lack the spatial control needed for performance MEMS devices. Although the conventional etch process starts on an area having a selected diameter, the effect of the etch process extends beyond the etch dimension beyond the desired area, leading to reduced control of the material removal process.

In the early prior art of laser ablation, lasers were used to provide a directed source of radiation whose deposited laser energy lead to the thermal heating of the substrate. However, there are many situations where heating is not desired and is, in fact, harmful. In these situations, such lasers may not be used. For example, long wavelength lasers, such as infrared lasers, which cut by heating a material substrate rather than by controlled photochemical ablation, are normally not desirable for etching since the etched region undergoes heating effects leading to uncontrolled melting.

Short pulse width infrared lasers exhibit some improvement in the control of the etch process as pulse width is reduced. For example, U.S. Pat. No. 5,656,186, Morrow et al. describes a laser with a pulse width of 100 fs to 1 ps at a 800 nm wavelength. See also, U.S. Pat. Nos. 7,560,658, 7,649,153 and 7,671,295.

Laser ablation using short pulses at long wavelength typically involves Ti:Sapphire (Ti:A10₃) lasers with pulses of 100 fs (0.1 ps) at a wavelength of 800 nm. The 100 fs pulse avoids phonon-phonon or electron-phonon coupling, which begins to occur at about 1.0 ps, but requires threshold intensities in excess or 10¹³ W/cm² and has a per pulse ablation depth of 300-1,000 nm. This per pulse ablation depth is greater than the thickness of many microcircuit layers, which is makes it an ineffective method for microcircuit processing.

Alternatively, long pulse width, short wavelength lasers may etch materials efficiently, but the etch process is still not adequately controlled. See, e.g., U.S. Pat. Nos. 4,925,523 and 7,469,831. Under these conditions, the laser deposits energy in a layer close to the surface of the material to be etched. A molten area forms leading to vaporization of the surface. The vapor pressure of the material aids removing the material by expulsion. Strong shock waves or the expulsion then lead to splatter, casting of material, and thermal cracking of the substrate, which interferes with the clean removal of the material.

Laser ablation using long pulses at short wavelength typically involves UV KrF excimer lasers, or similar ultraviolet lasers, with pulses of 1.0 ns or longer at a wavelength of 248 nm. However, this technique produces uncontrolled ablation with spalling and cratering. Such uncontrolled ablation is a result of the heating and melting of the material to be ablated beyond the laser spot size due to thermal (phonon-phonon) coupling during the laser pulse.

Thus, current technologies for laser ablation of materials use either long pulses at short wavelength or short pulses at long wavelength. Both technologies have significant shortcomings as described above.

In contrast, Applicants' have demonstrated the ablation materials using lasers that have a short pulse length at a short wavelength. Such lasers remove material without undue heating or damage to the areas surrounding the laser and have the depth control desired. The present invention also uses spectroscopic measurements to control the ablation by limiting it to the GaN layer.

It is a goal of the present invention to achieve controlled laser ablation through the use of short pulse lengths, short wavelengths, and the lowering of the threshold intensity required for ablation in materials such as GaN. It is also a goal of the present invention to stop the ablation at the boundary of the GaN layer or at an electrical contact (metal pad) on the MMIC device through spectroscopic measurements.

### SUMMARY

The present invention is a method and apparatus for the fabrication of vias in the GaN layer of GaN MMICs. It involves the use of lasers that have a short pulse length at a short wavelength to ablate material without undue heating or damage to the surrounding areas and with desired depth control. It also involves the use of spectroscopic measurements to stop the ablation of the boundary of the GaN layer.

One aspect of the present invention is a method of fabricating vias in a SiC MMIC having at least one GaN layer through the use of controlled laser ablation comprising, providing a MMIC having a plurality of layers; applying laser pulses in pulse widths of about 100 fs at wavelengths from about 340 nm to about 360 nm or from about 255 nm to about 270 nm to one or more layers of the MMIC; focusing the laser pulses, wherein the intensity of each pulse is 10¹² W/cm² or less; analyzing the excited particles ablated by the laser pulses to determine spectroscopically the current layer being ablated; and ablating the one or more layers thereby forming a via in the SiC MMIC.

One embodiment of the method of fabricating vias in a SiC MMIC having at least one GaN layer is wherein the laser is a frequency shifted Ytterbium laser.

One embodiment of the method of fabricating vias in a SiC MMIC having at least one GaN layer further comprises the step of detecting the presence of GaN layer.

One embodiment of the method of fabricating vias in a SIC MMIC having at least one GaN layer further comprises the step of stopping ablation at the GaN layer.

One embodiment of the method of fabricating vias in a SiC MMIC having at least one GaN layer further comprises the step of detecting the presence of a contact layer.

One embodiment of the method of fabricating vias in a SiC MMIC having at least one GaN layer further comprises the step of stopping ablation at the contact layer.

One embodiment of the method of fabricating vias in a SiC MMIC having at least one GaN layer is wherein the wavelength is about 355 nm.

One embodiment of the method of fabricating vias in a SiC MMIC having at least one GaN layer is wherein the wavelength is about 262 nm.

One embodiment of the method of fabricating vias in a SiC MMIC having at least one GaN layer is wherein the step of ablating occurs as a depth of less than 100 nm per pulse.

One aspect of the present invention is a method for fabricating vias in a CVD diamond MMIC having at least one GaN layer through the use of controlled laser ablation comprising providing a MMIC having a plurality of layers; applying laser pulses in pulse widths of about 100 fs at wavelengths about 340 nm to about 360 nm or from about 255 nm to about 270 nm to one or more layers of the MMIC; focusing the laser pulses, wherein the intensity of each pulse is 10¹² W/cm² or less; analyzing the excited particles ablated by the laser pulses to determine spectroscopically the current layer being ablated; and ablating the one or more layers thereby forming a via in the CVD diamond MMIC.

One embodiment of the method of fabricating vias in a CVD diamond MMIC having at least one layer is wherein the laser is a frequency shifted Ytterbium laser.

One embodiment of the method of fabricating vias in a CVD diamond MMIC having at least one GaN layer further comprises the step of detecting the presence of a GaN layer.

One embodiment of the method of fabricating vias in a CVD diamond MMIC having at least one GaN layer further comprises the step of stopping ablation at the GaN layer.

One embodiment of the method of fabricating vias in a CVD diamond MMIC having at least one GaN layer further comprises the step of detecting the presence of a contact layer.

One embodiment of the method of fabricating vias in a CVD diamond MMIC having at least one GaN layer further comprises the step of stopping ablation at the contact layer.

One embodiment of the method of fabricating vias in a CVD diamond MMIC having at least one GaN layer is wherein the wavelength is about 355 nm.

One embodiment of the method of fabricating vias in a CVD diamond MMIC having at least one GaN layer is wherein the wavelength is about 262 nm.

One embodiment of the method of fabricating vias in a CVD diamond MMIC having at least one GaN layer is wherein the step of ablating occurs as a depth of less than 30 nm per pulse.

These aspects of the invention are not meant to be exclusive and other features, aspects, and advantages of the present invention will be readily apparent to those of ordinary skill in the art when read in conjunction with the following description, appended claims, and accompanying drawings.

### BRIEF DESCRIPTION OF THE DRAWINGS

The foregoing and other objects, features, and advantages of the invention will be apparent from the following description of particular embodiments of the invention, as illustrated in the accompanying drawings in which like reference characters refer to the same parts throughout the different views. The drawings are not necessarily to scale, emphasis instead being placed upon illustrating the principles of the invention.

FIG. 1 is a schematic diagram of a via;

FIG. 2 is a schematic diagram of a preferred embodiment of the present invention;

FIG. 3 is as drawing of the band gap structure of GaN;

FIG. 4 is a plot of the absorption coefficient versus the photon energy of photons in GaN;

FIG. 5 is a schematic drawing of a preferred embodiment of the present invention; and

FIG. 6 is a table of information concerning the wavelength of emitted spectral lines.

### DETAILED DESCRIPTION OF PREFERRED EMBODIMENTS

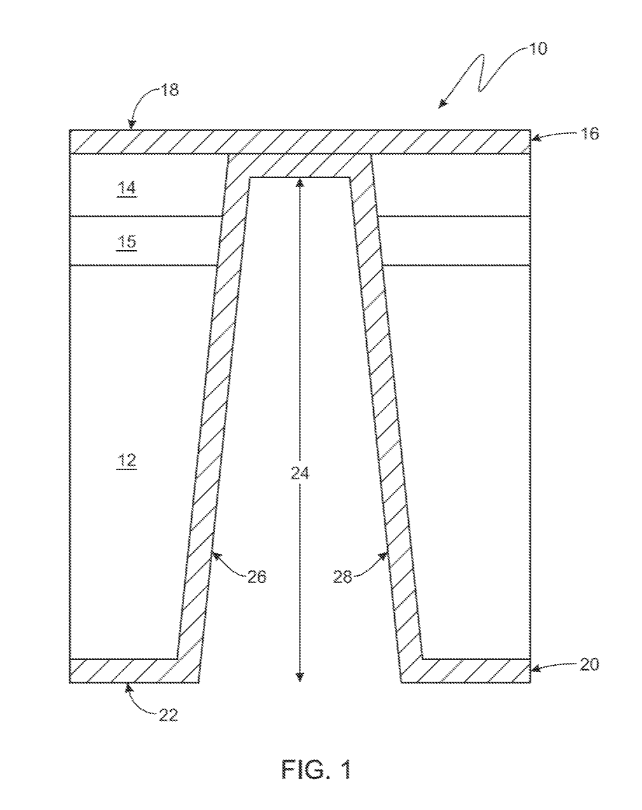

In FIG. 1, a section of a power RF circuit or other semiconductor device 10 is shown to demonstrate a via. The high power RF circuit (MMIC) or other semiconductor device 10 includes a substrate 12 and a GaN material device region 14 formed over the substrate. The substrate 12 is comprised of a material, which include, but are not limited to SiC and CVD diamond. As described further below, device structures are typically formed, at least in part, within GaN material region 14. Device 10 further includes a non-electrically conducting layer 15 formed on a non-electrically conducting substrate 12, for example, to facilitate the subsequent deposition of GaN material device region 14. A topside electrical contact 16 (on a topside 18 of the device) and a backside electrical contact 20 (on a backside 22 of the device) are provided for connection to an external power supply that powers the device. Backside contact 20 is deposited within at via 24 that extends from backside 22 of the device. Via 24 extends through the non-electrical conducting layers 12 and 15 and into a conducting region (e.g., device region 14) within device 10. As a result of the deposition of backside contact 20 within via 24, current can flow between the backside contact and topside contact 16 through device region 14 without being blocked by non-electrically conducting layer 15. Thus, vertical conduction through device 10 between backside contact 20 and topside contact 16 may be achieved despite the presence of non-conducting layer 15.

As used herein, “non-electrically conducting” refers to a layer that prevents current flow or limits current flow to negligible amounts in one or more directions. “Non-electrically conducting” layers, for example, may be formed non-electrical conductor materials, or may be formed of semiconductor materials, which have a band sufficiently offset from the layer adjacent the “non-electrically conducting” layer. A “non-electrically conducting” layer may be conductive in and of itself, but may still be non-electrically conducting (e.g., in a vertical direction) as a result of a band offset or discontinuity with an adjacent layer. As used herein, “vertical conduction” refers to electrical current flow in a vertical direction within a device. “Vertical conduction” may be between backside contact and topside contact or may be between different layers within the device that are separated vertically.

It should be understood that when a layer is referred to as being “on” or “over” another layer or substrate, it can be directly on the layer or substrate, or an intervening layer also may be present. A layer that is “directly on” another layer or substrate means that no intervening layer is present. It should also be understood that when a layer is referred to as being “on” or “over” another layer or substrate, it may cover the entire layer or substrate, or a portion of the layer or substrate. As shown in the figures, the term “topside” refers to the upper surface of the device and the term “backside” refers to the bottom surface of the device. Thus, the topside is opposite the backside of the device.

Previously, non-electrically conducting layer 15 would be formed on substrate 12 prior to the deposition of GaN material device region 14, for example, to accomplish one or more of the following: reducing crack formation in GaN material device region 14 by lowering thermal stresses arising from differences between the thermal expansion rates of GaN material device region 14 and substrate 12; reducing defect formation in GaN material device region 14 by lowering lattice stresses arising from differences between the lattice constants of GaN material device region 14 and substrate 12; and, increasing conduction between substrate 12 and GaN material device region 14 by reducing differences between the band gaps of substrate 12 and GaN material device region 14. It should be understood that non-electrically conducting layer 15 also may be formed between non-electrically conducting substrate 12 and GaN material device region for a variety of other reasons.

In certain embodiments, this non-electrically conducting layer 15 can be composed of AlN (aluminum nitride) or of a layer of AlGaN (aluminum gallium nitride) depending on whether the substrate is SiC or CVD Diamond. An adhesive layer might also be needed in the case of CVD Diamond to facilitate the attachment of the GaN/AlGaN layer to the CVD Diamond. It is understood that various non-electrically conducting layers can be used to provide the benefits described herein and they may differ depending on the corresponding substrate.

Still referring to FIG. 1, the via 24 extends through the non-electrically conducting layer 15 so that vertical conduction can occur in device 10. Thus, at a minimum, via 24 has a length 26 sufficient to create a conducting vertical path between topside contact 16 and backside contact 20. Via 24, for example, may extend to a position within the GaN material device region 14 to form such a conducting path. In some cases, via 24 may extend to a source region or a drain region formed within device 10.

The exact shape and dimensions of via 24 depend upon the application. A typical cross-sectional area of a via has dimensions of less than 100 microns by about 100 microns. In certain embodiments, the via is about 30 microns by about 30 micron at backside 22. In certain embodiments, it may be preferable for via 24 to be tapered inward, as shown, thus giving the via a cone shape. The inward taper can facilitate deposition of backside contact 20 on sidewalls 28 of via 24, if needed. In FIG. 1, device 10 includes a single via 24. Other embodiments may include more than one via.

As used herein, the phrase “electrical contact” or “contact” refers to any conducting structure on the semiconductor device that may be effectively contacted by a power source including electrodes, terminals, contact pads, contact areas, contact regions and the like. Backside contact 20 and topside contact 16 are formed of conducting materials including certain metals. Any suitable conducting material known in the art may be used. The composition of contacts 16, 20 may depend upon the type of contact. For example, contacts 16, 20 may contact n-type material or p-type material. Suitable metals for n-type contacts include titanium, nickel, aluminum, gold, molybdenum, tantalum, copper, and the like, and alloys thereof. Suitable metals for p-type contacts include nickel, gold, molybdenum, tantalum, titanium, and the like, and alloys thereof.

In certain embodiments, backside contact 20 may provide an effective attachment to a heat sink. In these embodiments, backside contact 20 removes thermal energy generated during the operation of the device. This may enable device 10 to operate under conditions that generate amounts of heat that would otherwise damage the device. In particular, high power RF circuits and laser diodes that operate at high current densities may utilize backside contact 20 as a heat sink. In certain embodiments, backside contact 20 may be specifically designed to enhance thermal energy removal. For example, backside contact 20 may be composed of materials such as copper and gold, and the like, which are particularly effective at removing heat. Also, backside contact 20 and via 24 may be designed so that a large surface area is in contact with device region 14, for example, by including multiple vias and/or vias that extend significantly into device region 14.

In certain embodiments, the GaN material device region 14 comprises at least one GaN material layer. In some cases, the GaN material device region 14 includes only one GaN material layer. In other cases, the GaN material device region 14 includes more than one epitaxial GaN material layer with varying dopant concentrations. The different layers can form different regions of the semiconductor structure. In certain embodiments, the GaN material region may also include one or more layers that do not have a GaN material composition such as oxide layers, metallic layers, or the like.

In certain embodiments of the present invention, high power MMICs are fabricated in GaN which is an epitaxial layer ˜1 micron thick on a substrate of either SiC or CVD diamond ˜100-200 microns thick. The substrate (e.g., SiC or CVD diamond) is used to support the thin GaN layer and to remove the heat generated. Vias are needed in the substrate and the GaN layer to construct a MMIC. As seen in FIG. 1, the vias may need to go through the substrate. In certain other embodiments of the present invention, the via may need to stop at the GaN layer. In certain other embodiments of the present invention, the via may need to go through the GaN layer and stop at the electrical contacts (e.g., metal pads).

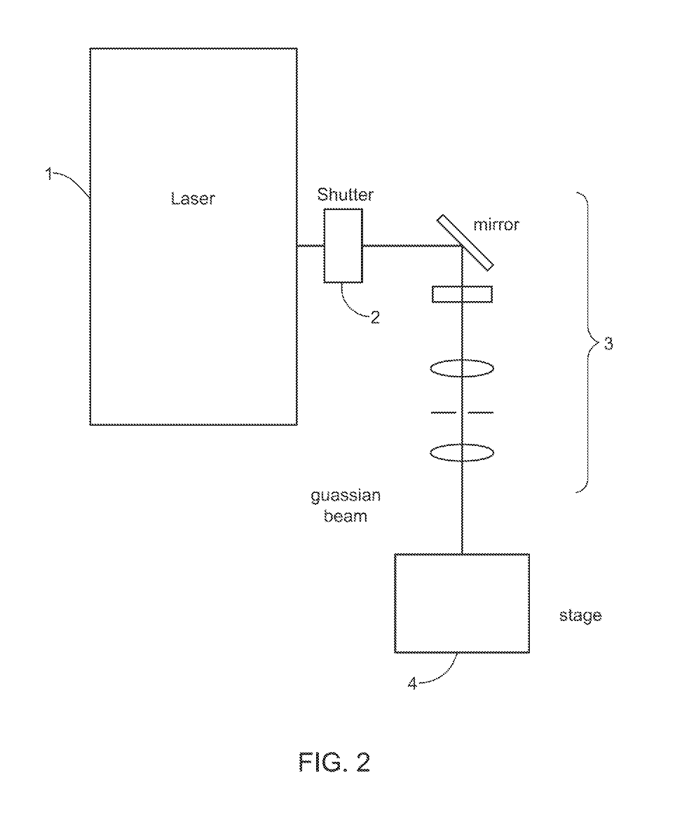

A preferred embodiment of the present invention is a method and apparatus to utilize lasers with short pulse widths at short wavelengths to produce controlled ablation of and around the GaN layer. It should be noted that the term laser as used herein includes frequency shifted laser systems. As shown in FIG. 2, a preferred embodiment of the present invention uses a frequency tripled or frequency quadrupled Yb:KYW (ytterbium ions in a lattice of potassium yttrium tungstate) laser 01 as the means for producing 100 fs pulses at wavelength raging form about 340 nm to about 360 nm and from about 255 nm to about 270 nm. In certain embodiments, the wavelength is about 355 nm or about 262 nm. The system of the present invention includes a shutter 02 and an arrangement of one or more mirrors and/or lenses 03, known to those skilled in the art, to focus a Gaussian beam or an appropriately structured beam on a stage 04. Also, other means known to those skilled in the art may be used to produce laser pulses with short pulse widths at short wavelengths.

It is understood that there are three ions that can be introduced into solid-state crystals that have a wide enough broadband gain to support the required 10⁻¹³ sec pulse duration used herein. They are Ti which operates at ˜800 nm wavelength, Cr which operates at ˜1200 nm wavelength, and Yb which operates at wavelengths from 1025 nm to 1080 nm depending on the crystal choice. The broadband solid state systems using Yb ions in crystals offer short pulses that can be amplified in a variety of architectures (including the regenerative amplifier being used in this program) in the correct wavelength region that can be frequency tripled and quadrupled to the desired short wavelength regimes.

In certain embodiments, a Yb crystal is used. Some of the Yb crystals include, but are not limited to, Yb:CaGdAlO₄ or Yb:CaAlGdO₄ also called Yb:CALGO, (Ytterbium in Calcium Gadolinium Aluminum Oxide Crystal); Yttrium Vanadate; Yb:YVO₄ (Ytterbium in Yttrium Vanadium Oxide Crystal); Yb:Sr₃Y(BO₃)₃ also called Yb:BOYS (Ytterbium in Strontium Yttrium Borate Crystal); Yb:GdCa₄O(BO₃)₃ also called Yb:GdCOB (Ytterbium in Gadolinium Calcium Borate Crystal); Yb:Sr₅(PO₄)₃F also called Yb:S—FAP and Yb:SrY₄(SiO₄)₃O also called Yb:SYS (Ytterbium in Apatite Crystals); Yb:KGd(WO₄)₂, Yb:KY(WO₄)₂ and Yb:KLu(WO₄)₂, also called. Yb:KGW, Yb:KYW, and Yb:KLuW (Ytterbium in Potassium Double Tungstate Crystals); Yb³⁺:NaGd(WO₄)₂, also called Yb:NGW and Yb³⁺:NaY(WO₄)₂ also called Yb:NYW) (Ytterbium in Tetragonal Double Tungstate Crystals); Yb:CaF₂ (Ytterbium in calcium fluoride crystal) and Yb:SrF₂ (Ytterbium in strontium fluoride crystal); Yb:phosphate glass; Yb:Y₂SiO₃ also called Yb:YSO, Yb:Lu₂SiO₃ also called Yb:LSO, Yb:Gd₂SiO₃ also called Yb:GSO (Ytterbium in oxyorthosilicate crystals); Sesquioxides: Yb:Y₂O₃ (Ytterbium in yttria crystal), Yb:Sc₂O₃ (Ytterbium in scandia crystal), Yb:Lu₂O₃ (Ytterbium in lutetia crystal and Yb₂O₃ (ytterbia); and the like.

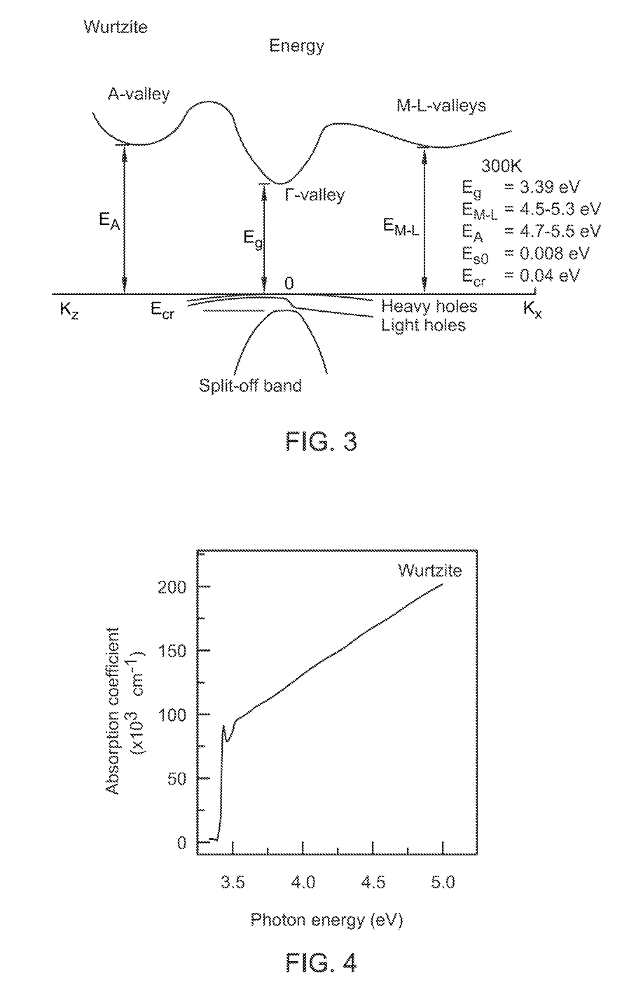

Gallium nitride has a direct band gap absorption of 3.39 eV as shown in FIG. 3 which leads to a dramatic increase in the absorption coefficient. This means that the absorption depth for radiation at a wavelength of 355 nm is 125 nm as shown in FIG. 4. In contrast, at a wavelength of 262 nm, the absorption depth for radiation is 50 nm. At wavelengths of 355 nm electrons are excited from the valence band to a very high energy state in the conduction band within this 125 nm (1250 Å) absorption depth, or in the case of 262 nm wavelength photons, 50 nm (500 Å) absorption depth. These highly placed electrons can be photoionized (excited to a free ion state) by absorbing another photon (1 free electron for 2 photons) or can exchange energy with a valence band electron to end up with two lower energy conduction band electrons, each of which can be photoionized in a single step (3 free electrons for 2 photons).

At intensities less than ˜10¹² W/cm² the excited electron density grows to the critical density for the 355 nm plasma frequency, n_{c}˜8.9 10²¹/cm³ or 1.6 10²²/cm³ for 262 nm radiation. Absorption then proceeds by a classic free carrier absorption model, but the absorption depth is now determined by the material parameters. It is estimated that the main burst of energy will be absorbed in either ˜50 nm (for 355 nm radiation) or 30 nm (for 355 nm radiation) with an energy absorption of 10-30 kJ/cm³. At this point, the energetic electrons leave the GaN and a Coulombic explosion follows. In other words, when electrons become energetic enough, they will leave the material surface leaving behind positively charged ions that then fly apart due to electrostatic forces. This creates a shock that blows away the material without any melting.

In certain embodiments of the present invention, the ablation depth is less than about 100 nm. In certain embodiments, the ablation depth is less than about 30 nm. IN certain embodiments the ablation depth is about 100 nm, about 90 nm, about 80 nm, about 70 nm, about 60 nm, about 50 nm, about 40 nm, or about 30 nm. In certain embodiments, the ablation depth is about 25 nm, about 20 nm, about 15 nm, about 10 nm, or about 5 nm. In certain embodiments, the ablation depth is about 4 nm, about 3 nm, about 2 nm, or about 1 nm.

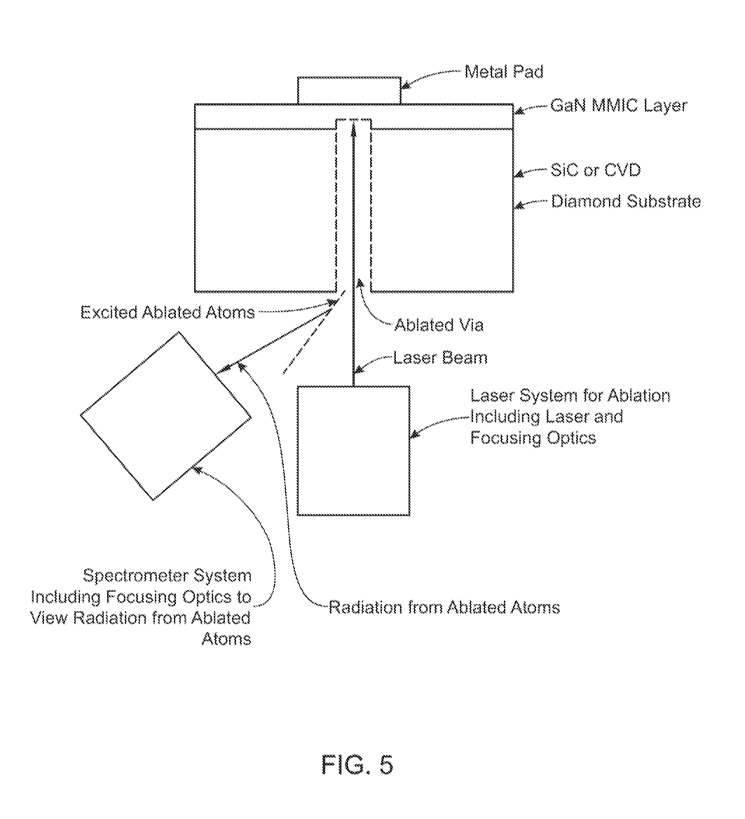

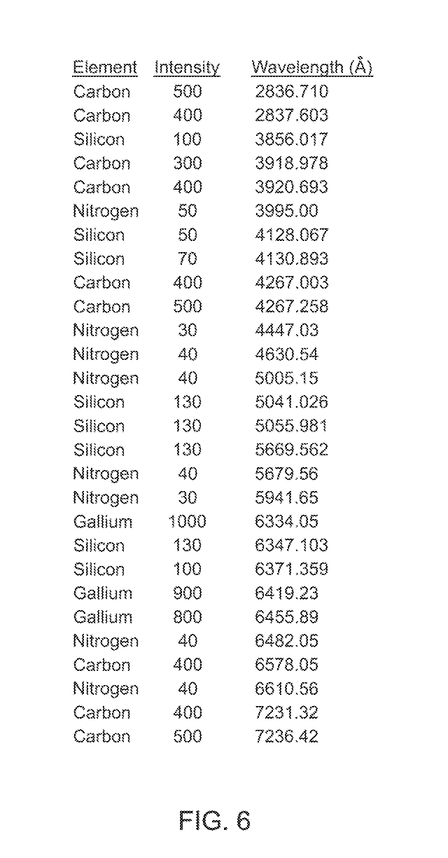

In another preferred embodiment, the ablation is stopped at the boundary of the GaN layer. In certain embodiments, the ablation is stopped at the electrical contacts (e.g., metal pads) on the field effect transistor (“FET”) sources or drains. In certain embodiments, the ablation is stopped by using spectroscopic measurements to sense which materials are being ablated, as shown in FIG. 5. As the laser beam ablates the via, excited atoms escape via Coulombie explosion. The atoms will be excited neutral atoms or excited ions and will emit radiation over a great number of individual spectral lines. In the case of SiC, the excited particles will be excited silicon or carbon atoms. In the case of CVD diamond, they will be excited carbon atoms. In the case of GaN, they will be excited gallium and nitrogen atoms. In certain embodiments, in the case of GaN the atoms will be excited gallium, nitrogen, aluminum, or other atoms depending on the layered structure of the particular via to be ablated. FIG. 6 shows some of the possible resulting emitted spectral lines. The bandwidth of the emitted spectral lines will be very narrow, in the GHz range (10⁻³ nm).

The NIST handbook provides a selection of the most important and frequently used atomic spectroscopic data, which are identified as ‘persistent’ lines for each ionized element through spectroscopic observations made with low concentrations of a particular element relative to other substances in the source. The exemplary compilation of data in FIG. 6 is for singly-ionized atoms of Carbon, Silicon, Gallium, and Nitrogen for wavelengths between 2500-8000 Angstroms. Ionized Arsenic does not have a ‘persistent’ emission line in this range. It is recognized that interactions with other elements including neutral states of the element being tested are likely to result in additional transition lines than those involved in the listed persistent-line transitions.

The relative intensities of the spectral lines observed for these exemplary elements depend upon the light source and excitation conditions. The relative intensities observed and reported and tabulated by NIST are adjusted to correct for the wavelength dependence of the sensitivity of the spectrometer and detector. An intensity of 1000 has been assigned to the strongest line(s) of each spectrum.

In certain embodiments, the spectroscopic detection system of the present invention utilizes one or more transition lines either singularly or in combination to determine when to cease the series of laser pulses that result in the controlled ablation of the unique electronic layers consisting of various elemental materials.

As an example, a SiC layer that is being formed into a via and overlays the GaN and/or GaAs layers in the following manner would be as follows: the transition from the SiC emission in the 412-427 nm range could be monitored in relationship to the GaN emission in the 633 nm, and 642-646 nm spectrum; the transition from the GaN emission as the via forming process progresses into the GaAs layer by could be monitored by monitoring the Ga emissions in the 633 nm, and 642-646 nm spectrum range in relationship to the N emission in the 445-501 nnn, 568 nm, 594 nm, 648 nm, and 661 nm spectrum.

The spectra of all the constituents from the ablated material is measured using a spectrometer system which captures the entire spectra using a CCD sensor. The spectra is studied carefully to allow controlled ablation on a per pulse basis. Given the large number or spectral lines, emitted lines for one species can be found that are different than any of the other species. Thus, any single species can be uniquely identified as a result of this analysis. The information can be used to control the ablation in via fabrication. For example, as the ablation proceeds in SiC, silicon and carbon spectral lines will be identified. Gallium or nitrogen spectra will be identified when the ablated hole is in the GaN layer. In certain embodiments, the ablation in SiC proceeds at less than about 100 nm/pulse, so the ablation can easily be terminated in the GaN if desired. In certain embodiments, the ablation in CVD diamond proceeds at less than about 30 nm/pulse, so the ablation can easily be terminated in the GaN if desired. In certain embodiments, ablation can continue to the electrical contact (e.g., metal pad) and stop when the metal spectra is measured.

While the principles of the invention have been described herein, it is to be understood by those skilled in the art that this description is made only by way of example and not as a limitation as to the scope of the invention. Other embodiments are contemplated within the scope of the present invention in addition to the exemplary embodiments shown and described herein. Modifications and substitutions by one of ordinary skill in the art are considered to be within the scope of the present invention.

What is claimed:

1. A method of fabricating vias in a SiC MMIC having at least one GaN layer through the use of controlled laser ablation comprising,
providing a MMIC having a plurality of layers;
applying laser pulses in pulse widths of about 100 fs at wavelengths from about 340 nm to about 360 nm or from about 255 nm to about 270 nm to one or more layers of the MMIC;
focusing the laser pules, wherein the intensity of each pulse is 10¹² W/cm² or less;
analyzing the excited particles ablated by the laser pulses to determine spectroscopically the current layer being ablated; and
ablating the one or more layers thereby forming a via in the SiC MMIC.

2. The method of fabricating vias in a SiC MMIC having at least one GaN layer of claim 1, wherein the laser is a frequency shifted Ytterbium laser.

3. The method of fabricating vias in a SiC MMIC having at least one GaN layer of claim 1, further comprising the step of detecting the presence of a GaN layer.

4. The method of fabricating vias in a SiC MMIC having at least one GaN layer of claim 3, further comprising the step of stopping ablation at the GaN layer.

5. The method of fabricating vias in a SiC MMIC having at least one GaN layer of claim 1, further comprising the step of detecting the presence of a contact layer.

6. The method of fabricating vias in a SiC MMIC having at least one GaN layer of claim 5, further comprising the step of stopping ablation at the contact layer.

7. The method of fabricating vias in a SiC MMIC having at least one GaN layer of claim 1, wherein the wavelength is about 355 nm.

8. The method of fabricating vias in a SIC MMIC having at least one GaN layer of claim 1, wherein the wavelength is about 262 nm.

9. The method of fabricating vias in a SiC MMIC having at least one GaN layer of claim 1, wherein the step of ablating occurs as a depth of less than 100 nm per pulse.

10. A method for fabricating vias in a CVD diamond MMIC having at least one GaN layer through the use of controlled laser ablation comprising,
providing a MMIC having a plurality of layers;
applying laser pulses in pulse widths of about 100 fs at wavelengths about 340 nm to about 360 nm or from about 255 nm to about 270 nm to one or more layers of the MMIC;
focusing the laser pulses, wherein the intensity of each pulse is 10¹² W/cm² or less;
analyzing the excited particles ablated by the laser pulses to determine spectroscopically the current layer being ablated; and
ablating the one or more layers thereby forming a via in the CVD diamond MMIC.

11. The method of fabricating vias in a CVD diamond MMIC having at least one GaN layer of claim 10, wherein the laser is a frequency shifted Ytterbium laser.

12. The method of fabricating vias in a CVD diamond MMIC having at least one GaN layer of claim 10, further comprising the step of detecting the presence of a GaN layer.

13. The method of fabricating vias in a CVD diamond MMIC having at least one GaN layer of claim 12, further comprising the step of stopping ablation at the GaN layer.

14. The method of fabricating vias in a CVD diamond MMIC having at least one GaN layer of claim 10, further comprising the step of detecting the presence of at contact layer.

15. The method of fabricating vias in a CD diamond MMIC having at least one GaN layer of claim 14, further comprising the step of stopping ablation at the contact layer.

16. The method of fabricating vias in a CVD diamond MMIC having at least one GaN layer of claim 1, wherein the wavelength is about 355 nm.

17. The method of fabricating vias in a CVD diamond MMIC having at least one GaN layer of claim 1, wherein the wavelength is about 262 nm.

18. The method of fabricating vias in a CVD diamond MMIC having at least one GaN layer of claim 1, wherein the step of ablating occurs as a depth of less than 30 nm per pulse.
